(19) United States
(12) Patent Application Publication
(10) Pub. No.: US 2013/0062656 A1
(43) Pub. Date: Mar. 14, 2013

(54) THERMALLY ENHANCED OPTICAL PACKAGE

(71) Applicants: WEI CHIH LEE, NEW TAIPEI CITY (TW); SHIH KWAN LIU, HSINCHU CITY (TW); HUAI LUH CHANG, NEW TAIPEI CITY (TW)

(72) Inventors: WEI CHIH LEE, NEW TAIPEI CITY (TW); SHIH KWAN LIU, HSINCHU CITY (TW); HUAI LUH CHANG, NEW TAIPEI CITY (TW)

(73) Assignee: INPAQ TECHNOLOGY CO., LTD., MIAOLI (TW)

(21) Appl. No.: 13/231,020

(22) Filed: Sep. 13, 2011

(51) Int. Cl. H01L 33/64

(52) U.S. Cl. 257/99; 438/26; 257/E33.075; 438/118

(57) ABSTRACT

A thermally enhanced optical package includes a heat conducting module configured to dissipate the heat generated from an optical device, a plurality of insulating pads disposed on a heat conducting substrate, and at least one electrical conducting pad disposed on the insulating pads. The heat conducting module includes a heat conducting substrate and a plurality of heat conducting pillars, and the optical device is a light emitting diode chip or a light emitting diode die in the present embodiments. The thermally enhanced optical package is further characterized in a simple manufacturing procedure, including substantially an electrical or electroless plating process, a metal foil laminating process, a thick film printing process, and a patterning and etching process.

### BACKGROUND OF THE INVENTION

1. Technical Field

The present invention relates to a thermally enhanced optical package, and more particularly, to a light emitting diode (LED) multi-chip package having an enhanced heat dissipating structure using a simple manufacturing process.

2. Background

The research and development of light emitting diodes (LEDs) have focused on devices' luminance and efficiency; however, only 30% of the input power is converted into light while the other 70% is dissipated as heat. The dissipated heat not only consumes energy but also increases the temperature in the LED, which deteriorates device efficiency and alters color temperature. Therefore, heat management in LED is a crucial issue, the solution of which has been based on three levels: chip, packaging, and substrate. Among the three, the most effective one is the substrate level.

Current heat dissipating substrates can be categorized into plastic, fiberglass reinforced (FR4), metal, and ceramic substrates. The most prominent advantage of the plastic substrate lies in the versatile structure and the ease in mass production, but its heat conducting efficiency is the worst among the four. The plastic substrate is now well accepted in the low power LED (−0.3 W) sector. FR4 finds its niche in simple manufacturing and mass production, but the low thermal conductivity hinders the popularity in the high power LED sector. Currently metal core printed circuit board (MCPCB) is mainstream in high power LED sector due to superior thermal conductivity and convenience in processing. The bottleneck of MCPCB resides in the insulating layer in the structure. By adding fillers with high thermal conductivity to conventional epoxy, the thermal conductivity of the insulating layer is increased from 0.5 W/mK to 5 W/mK, which albeit a leap of an order in the thermal conductivity, is still considered too low and unreliable to meet current technology requirements. The other mainstream material of LED heat dissipating substrate is ceramic Al₂O₃ provides a more appealing thermal conductivity (20-30 W/mK), and this number can be further increased by using direct plating copper (DPC), or using AlN as an alternative substrate material. However, a high cost is the tradeoff for the desirable property.

As for the packaging level, level 1 and level 2 are introduced in the following for further classification. Level 1 packaging turns an LED die to a free standing LED chip, while level 2 deals with the packaging of multiple LED chips and arranges them into an array on the circuit board. FIG. 1 illustrates a cross sectional view of a conventional low power LED (<0.3 W) with level 1 packaging 10. A low power LED die 16 is disposed on a plastic leaded chip carrier (PLCC) 11, electrically connected to metal leads 12 through openings 15 via gold wires 13. The structure is covered by a dome-shaped encapsulant 14 and packaged by fluorescent adhesive. FIG. 2 illustrates a cross sectional view of a conventional high power LED (>0.5 W) with level 1 packaging 20. A high power LED die 26 is disposed on a Al₂O₃ or AlN substrate 21, electrically connected to two electrodes 22 through openings 25 via gold wires 23. The structure is covered by a dome-shaped encapsulant 24 and packaged by fluorescent adhesive. Level 1 packaging delivers a free standing LED chip, which is ready for level 2 packaging.

FIG. 3 illustrates a cross sectional view of a conventional high power LED in level 2 packaging 300 on an aluminum MCPCB 310 and an aluminum heat sink 311. The purpose of the level 2 packaging is to join a plurality of LED chips onto the PCB, together with circuit elements such as resistors, varistors, and transformers to complete a basic LED lighting structure. As shown in FIG. 3, a high power LED die 313 is disposed on a Al₂O₃ or AN substrate 301, electrically connected to metal contacts 302 through openings 305 via gold wires 303. The structure is covered by a dome-shaped encapsulant 304 and packaged by fluorescent adhesive (not shown). A patterned conductive pad 307 is in contact with the metal lead 302 and surrounded by a solder mask 308 on a dielectric layer 309. In this event, the dielectric layer 309 is required to be inserted between the conductive layer 307 and the MCPCB 310 in order to separate the electrical path from the MCPCB 310. A thermally conductive tape 312 is positioned between the MCPCB 310 and a heat sink 311 to join the two. The gap 306 between the ceramic substrate 301 and the solder mask 308 is filled with thermal adhesive containing fillers such as polymers, ceramic oxides, or metal to enhance the heat dissipation and to engage the free standing LED chip and the MCPCB.

In the above mentioned prior art, the heat management is limited by 1) the low thermal conductivity of the thermal adhesive and 2) the multiple conductor-insulator interfaces. The thermal conductivity of the packaging is as low as 2 W/mK by having the thermal adhesives and the multiple interfaces in the structure. Hence, an improved design either in level 1 or level 2 packaging is required to better control the thermal budget of the LED system.

### SUMMARY

One aspect of the present invention provides a thermally enhanced optical package, comprising a heat conducting module, a plurality of insulating pads, and at least one electrical conducting pad. The heat conducting module comprises a heat conducting substrate and a plurality of heat conducting pillars positioned on the heat conducting substrate, the plurality of insulating pads are disposed on the heat conducting substrate, and the at least one electrical conducting pad is disposed on the insulating pad and electrically connected to an optical device.

Another aspect of the present invention provides a method of manufacturing a thermally enhanced optical package comprising the following steps of forming a heat conducting module including a heat conducting substrate and a plurality of heat conducting pillars positioned on the heat conducting substrate; forming a plurality of insulating pads including at least one electrical conducting pad positioned on each of the insulating pads; binding the heat conducting module and the plurality of insulating pads; and forming an adhesion enhancing layer on the plurality of heat conducting pillars and the electrical conducting pads.

Another aspect of the present invention provides a method of manufacturing a thermally enhanced optical package comprising the step of forming a plurality of insulating pads with at least one electrical conducting pad positioned on each of the insulating pads; forming a first adhesion enhancing layer on electrical conducting pads; combining the plurality of insulating pads with a heat conducting substrate; forming a plurality of heat conducting pillars on the heat conducting substrate; and forming a second adhesion enhancing layer on the heat conducting pillars.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes as the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 is a cross sectional view illustrating a conventional low power LED package with metal lead frame;

FIG. 2 is a cross sectional view illustrating a conventional high power LED package with underlying circuit lines;

FIG. 3 is a cross sectional view illustrating a conventional high power LED package with an aluminum metal core printed circuit board (MCPCB) and an aluminum heat sink;

FIG. 4 is a cross sectional view illustrating a thermally enhanced high power LED package according to one embodiment of the present invention;

FIG. 5 to FIG. 10 show a manufacturing process flow of the embodiment shown in FIG. 4;

FIG. 11 is a cross sectional view illustrating a thermally enhanced high power LED package according to another embodiment of the present invention;

FIG. 12 to FIG. 18 show a manufacturing process flow of the embodiment shown in FIG. 11;

FIG. 19 is a cross sectional view illustrating a LED die with a metal layer attaching to a passive side of a substrate; and

FIG. 20 is a cross sectional view illustrating a thermally enhanced chip on board (COB) LED package according to still another embodiment of the present invention.

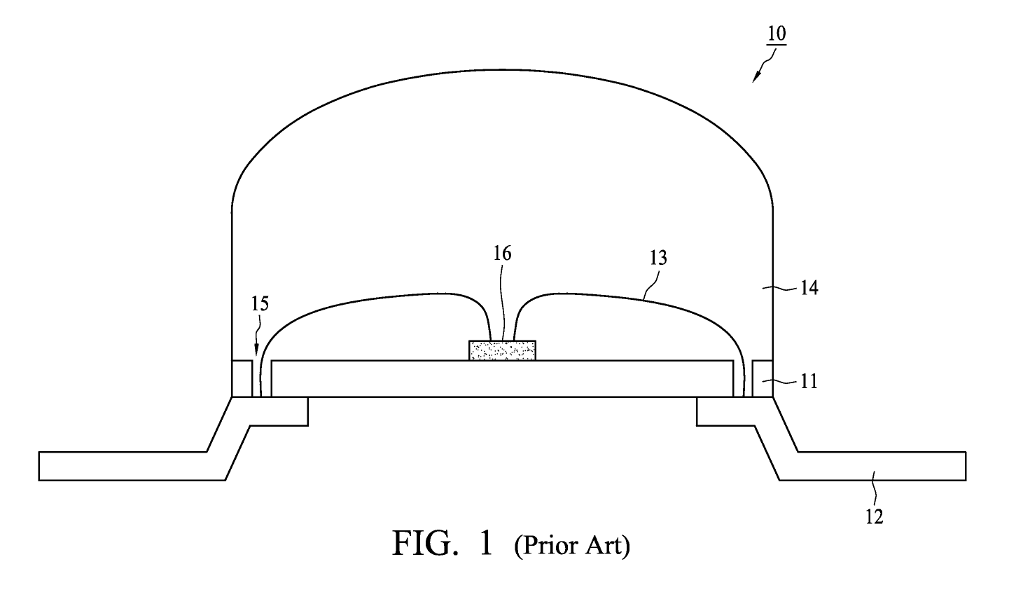

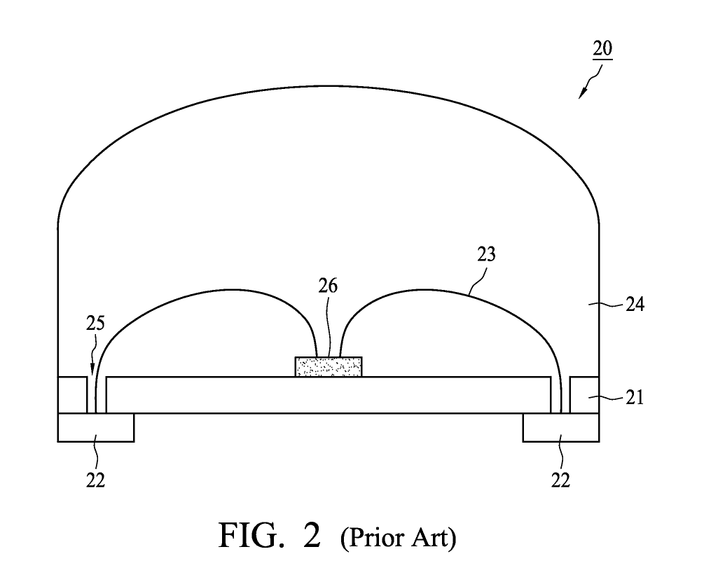

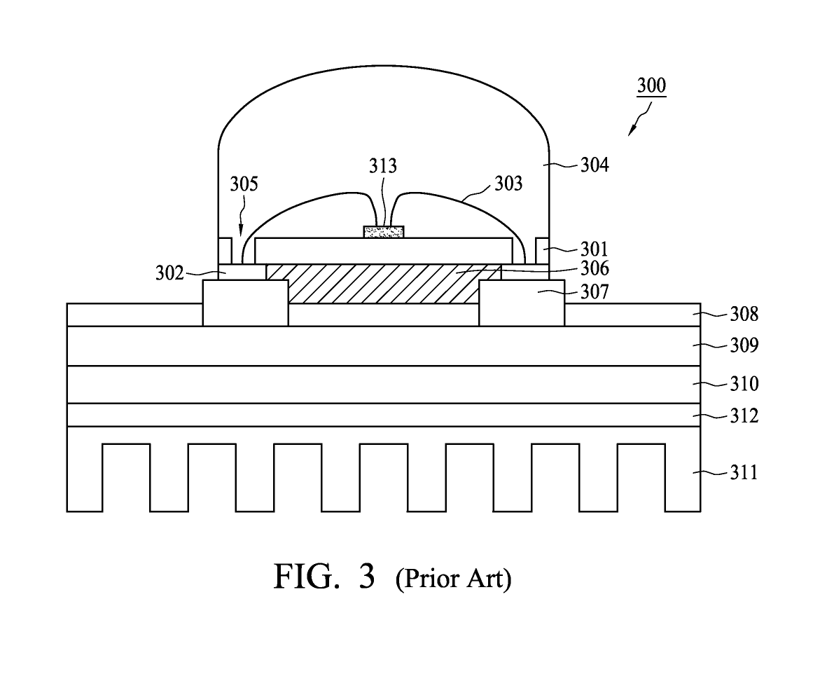

### DETAILED DESCRIPTION

One embodiment of the present invention discloses a structure with separated heat and electrical conducting paths. From the perspective of level 2 packaging, the embodiment of the present invention first replaces the thermal adhesive from the conventional structure with tin or other metals. This will allow chips completing level 1 packaging to utilize the entire bottom area as a major heat dissipating channel. Furthermore, a chip on board (COB) structure is presented in combining the aforementioned level 2 packaging and an LED die without conventional level 1 packaging. The new COB structure substantially decreases the number of the interfaces encountered in the heat dissipating path. Another aspect in the embodiment of the present invention is to disclose a simple manufacturing process of the new structure. Metals with high thermal conductivities are introduced to the structure by either conductive paste printing, metal foil laminating, or electrical/electroless plating.

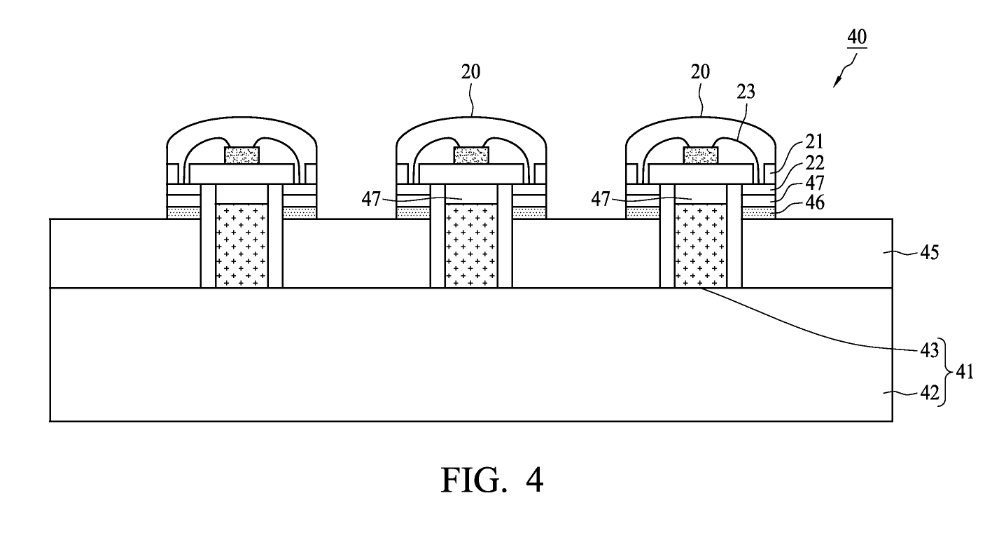

FIG. 4 is a cross sectional view illustrating a thermally enhanced high power LED package 40 according to one embodiment of the present invention. The high power LED package 40 comprises a heat conducting module 41, a plurality of insulating pads 45, and at least one electrical conducting pad 46. The heat conducting module 41 comprises a heat conducting substrate 42 and a plurality of heat conducting pillars 43 positioned on the heat conducting substrate 42; the plurality of insulating pads 45 are disposed on the heat conducting substrate 42, and the at least one electrical conducting pad 46 is disposed on the insulating pads 45. In the present embodiment, a plurality of optical devices 20 such as the high power LED chips with level 1 packaging are positioned above the heat conducting pillars 43, and electrically connected to the electrical conducting pads 46 via two electrodes 22 and the corresponding adhesion enhancing layers 47. The adhesion enhancing layer 47 comprises tin or nickel/palladium/gold.

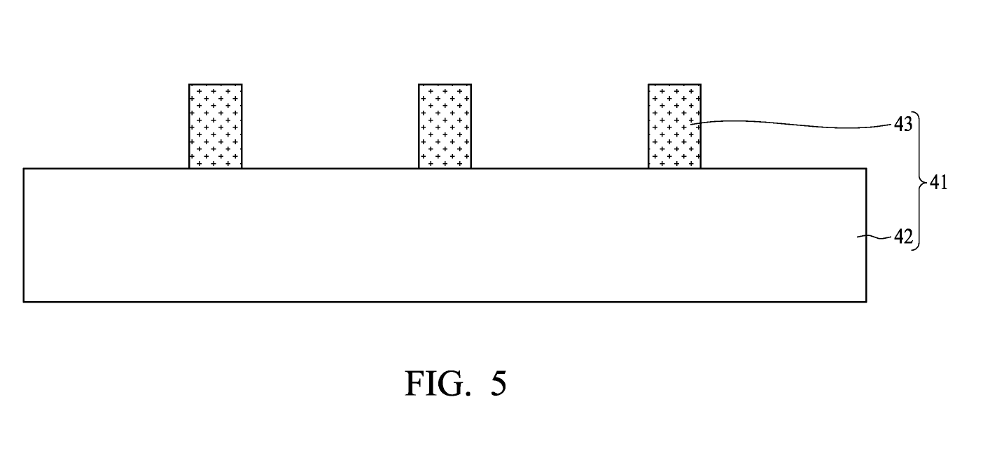

FIG. 5 to FIG. 10 show a manufacturing process flow of the embodiment shown in FIG. 4. In FIG. 5, a heat conducting substrate 42 with thermal conductivity higher than 100 W/mK is provided, for example, Al 3303, Al 3305 or other substrate made of aluminum or copper is preferred. Next, a patterned thick film comprises conductive paste is printed on the heat conducting substrate 42, and followed by a baking and sintering process to the conductive paste to obtain a solid conductor. The solid conductor forms a heat conducting pillar 43 positioned on the substrate 42, and together the heat conducting substrate 42 and the heat conducting pillar 43 form a heat conducting module 41. The material of the conductive paste, for example, can be Heraeus C8829B, or other conductive pastes comprising aluminum, silver, copper, silver-palladium, palladium, platinum powder, and the alloy powder combinations thereof. The printed pattern can be a plurality of squares or polygons.

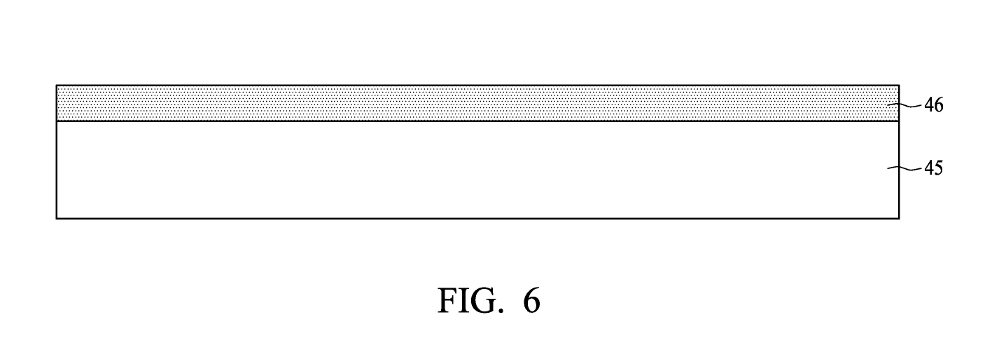

In FIG. 6 to FIG. 10, a plurality of insulating pads and at least one electrical conducting pad are assembled separately as described in the following step. A copper foil 46 is disposed on an insulating pad 45 comprising a double sided adhesion layer to form a bonded unit without pattern. The thickness of the copper foil 46 can be adjusted from ½ oz. to 3 oz. (17 μm-105 μm) to meet specific requirements. The thickness of the double sided adhesion layer can be in the range of 5 μm-150 μm. The material of the double sided adhesion layer can be a double sided tape, an epoxy, or other insulating pastes with adhesive properties.

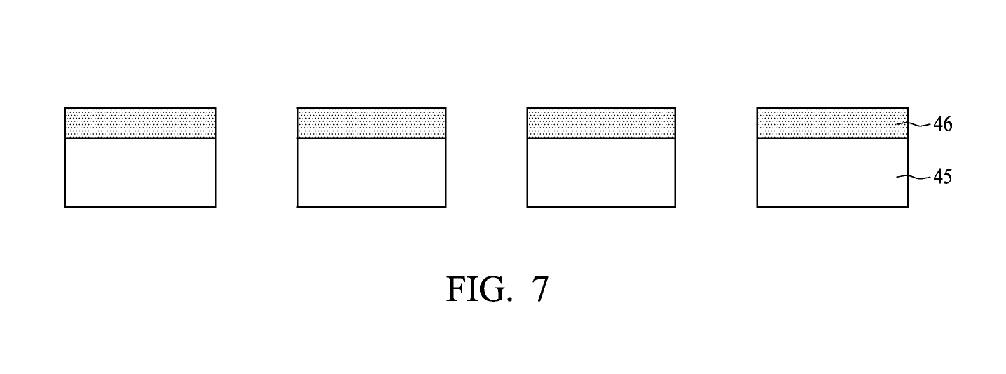

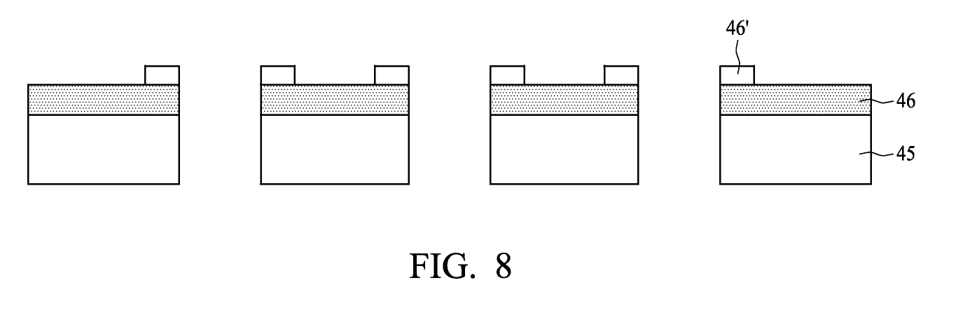

In FIG. 7, the bonded unit is then punched to form a specific pattern complementary to the pattern of the heat conducting pillars 43 shown in FIG. 5. In FIG. 8, a patterned gel body 46′ is printed on the copper foil 46 of the bonded unit. The pattern of the gel body 46′ is specially designed to form a predetermined circuit line. The material of the gel body 46′ can be a photoresist or an epoxy. In the next step, the gel body 46′ is hardened by undergoing a baking process.

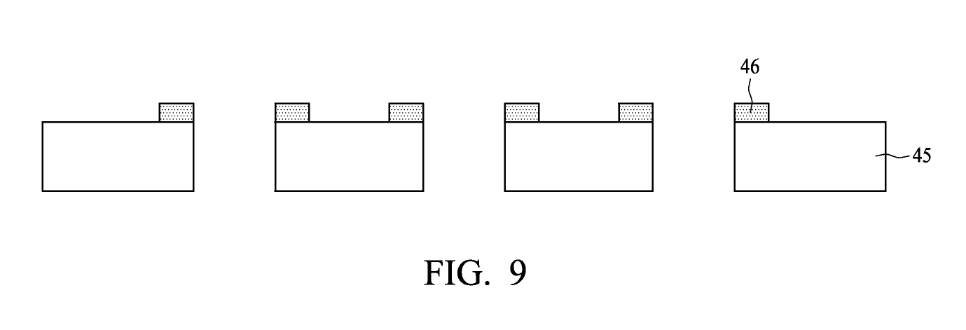

In FIG. 9, photolithography or a simple etching process can be used to remove the uncovered portion of the copper foil 46; chemical stripping, for example chemical wash, or physical stripping, for example, grinding, is then applied to remove the remaining gel body 46′.

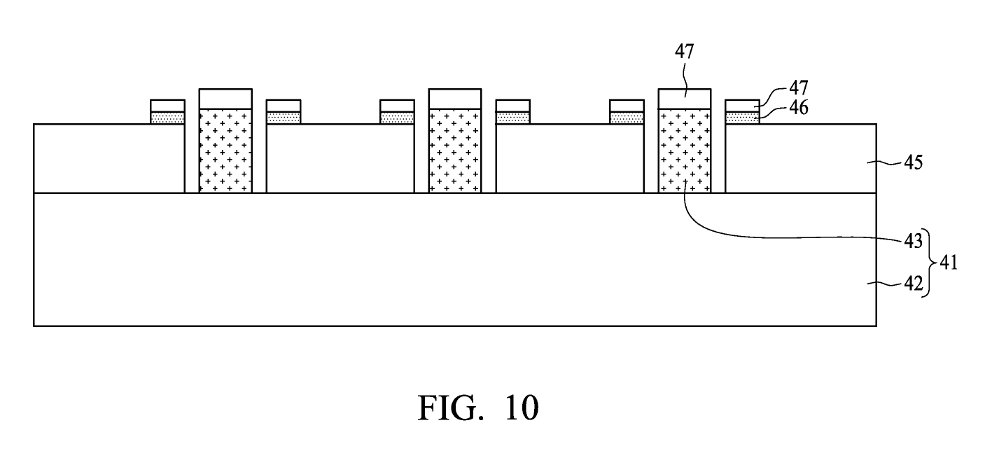

In FIG. 10, the heat conducting module 41 and the patterned bounded unit are aligned in a complementary fashion, and the two units are joined via the unoccupied adhesive surface of the double sided adhesion layer. An electrical or electroless plating process is performed to coat an adhesion enhancing layer 47 comprising tin or nickel/palladium/gold on the copper foil 46 and the heat conducting pillars 43. In one embodiment of the present invention, the top surface of the heat conducting pillars 43 is equal to or higher than the top surface of other elements in the structure. Referring back to FIG. 4, the optical device 20 is disposed on the heat conducting pillar 43, and is electrically connected to the electrical conducting pad 46 via two electrodes 22 and the corresponding adhesion enhancing layers 47. The adhesion enhancing layer 47 comprising tin or nickel/palladium/gold is coated on the electrical conducting pad 46 and the heat conducting pillar 43 prior to the placement of the optical device 20 in order to achieve better adhesion and lower contact resistance between different materials.

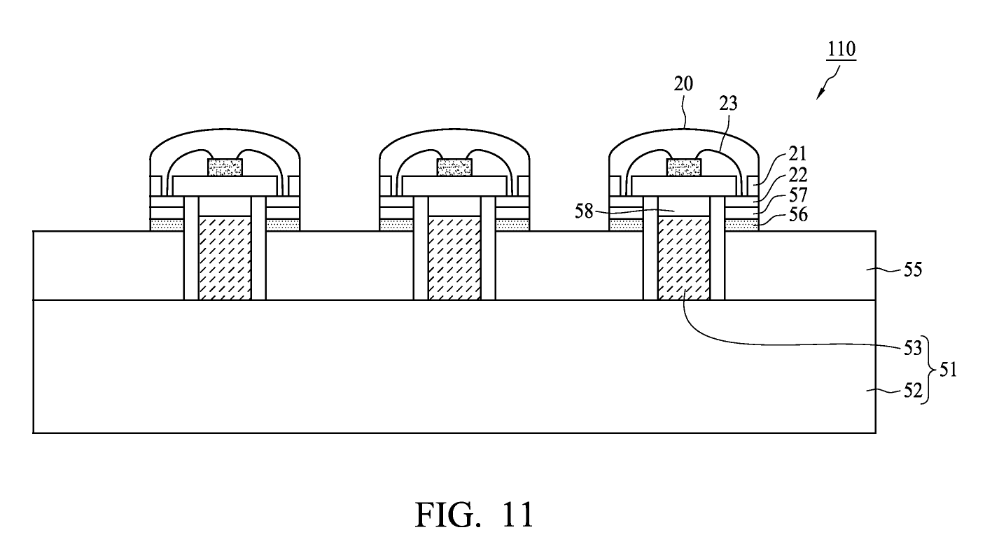

FIG. 11 is a cross sectional view illustrating a thermally enhanced high power LED package 110 according to another embodiment of the present invention. The thermally enhanced high power LED package 110 comprises a heat conducting module 51, a plurality of insulating pads 55, and at least one electrical conducting pad 56. The heat conducting module 51 comprises a heat conducting substrate 52 and a plurality of heat conducting pillars 53 positioned on the heat conducting substrate 52; the plurality of insulating pads 55 are disposed on the heat conducting substrate 52, and the at least one electrical conducting pad 56 is disposed on the insulating pads 55. In the present embodiment shown in FIG. 11, a plurality of optical devices 20 such as high power LED chips with level 1 packaging are positioned on the heat conducting pillars 53, and electrically connected to the electrical conducting pads 56 via two electrodes 22 and the corresponding first adhesion enhancing layers 57. The first adhesion enhancing layer 57 comprises tin or nickel/palladium/gold.

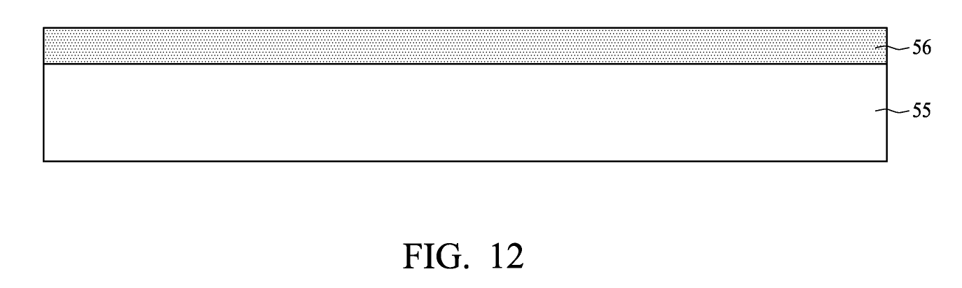

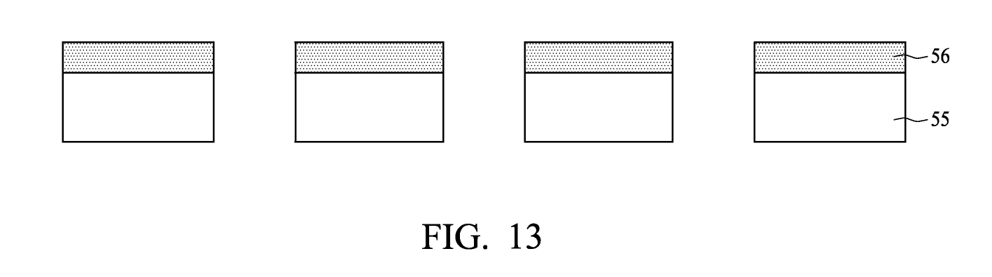

FIG. 12 to FIG. 18 show a process flow of the embodiment shown in FIG. 11. In FIG. 12, a copper foil 56 is disposed on an insulating pad 55 comprising a double sided adhesion layer to form a bonded unit without pattern. The thickness of the copper foil 56 can be adjusted from ½ oz. to 3 oz. (17 μm-105 μm) to meet specific requirements. The thickness of the double sided adhesion layer can be in the range of 5 μm-150 μm. The bonded unit is then punched to form a specific pattern, as shown in FIG. 13. The material of the double sided adhesion layer can be a double sided tape, an epoxy, or other insulating pastes with adhesive properties.

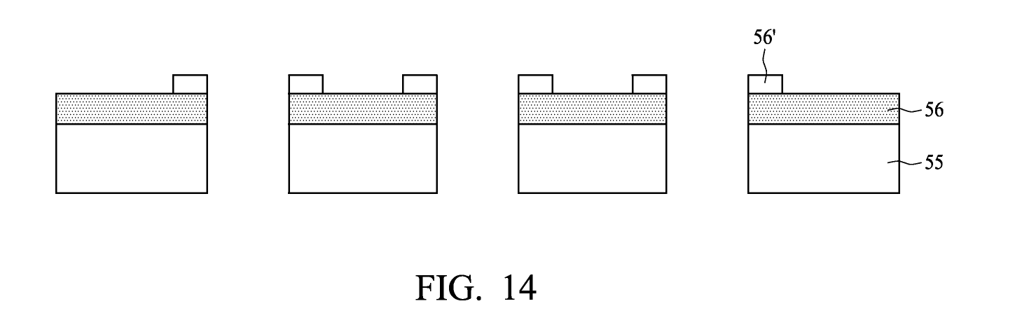

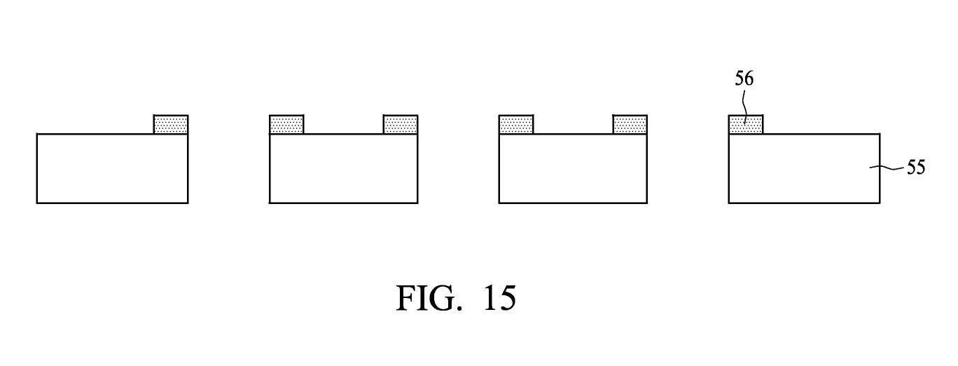

In FIG. 14, a patterned gel body 56′ is printed on the copper foil 56 of the bonded unit. The pattern of the gel body 56′ is specially designed to form a predetermined circuit line. The material of the gel body 56′ can be a photoresist or an epoxy. In the next step, the gel body 56′ is hardened by undergoing a baking process. Photolithography or a simple etching process can be used to remove the uncovered portion of the copper foil 56, as shown in FIG. 15. Chemical stripping, for example chemical wash, or a physical stripping, for example grinding, is then applied to remove the remaining gel body 56′.

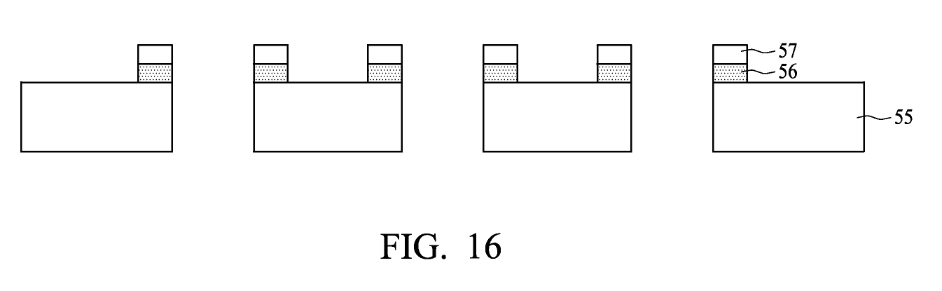

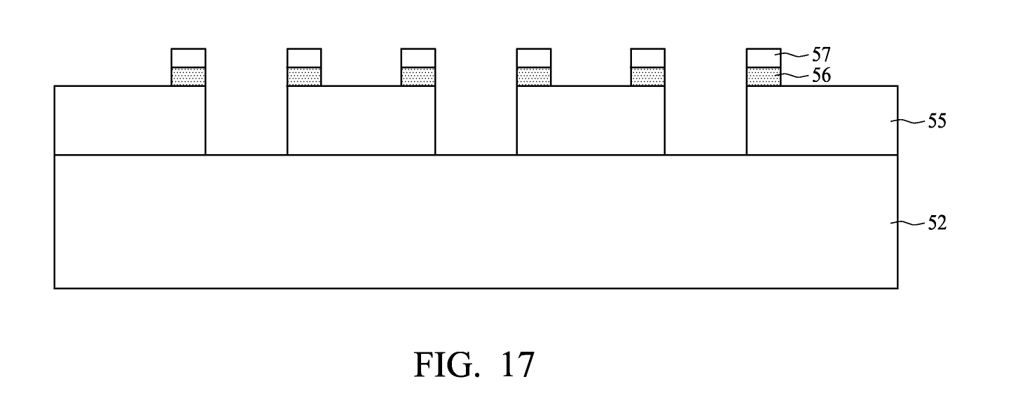

The subsequent step shown in FIG. 16 forms a first adhesion enhancing layer 57 comprising tin or nickel/palladium/gold on the copper foil 56 by an electrical/electroless plating process or a conductive paste printing process. A joining process between the insulating pads 55, the at least one electrical conducting pad 56, the first adhesion enhancing layer 57, and the heat conducting module 51 is described in the following steps: In FIG. 17, a heat conducting substrate 52 with thermal conductivity higher than 100 W/mK is provided, for example, Al 3303, Al 3305 or other substrate comprises aluminum, copper, or the alloy combinations thereof is preferred. The structure shown in FIG. 16 and the heat conducting substrate 52 shown in FIG. 17 are joined via the unoccupied adhesive surface of the double sided adhesion layer.

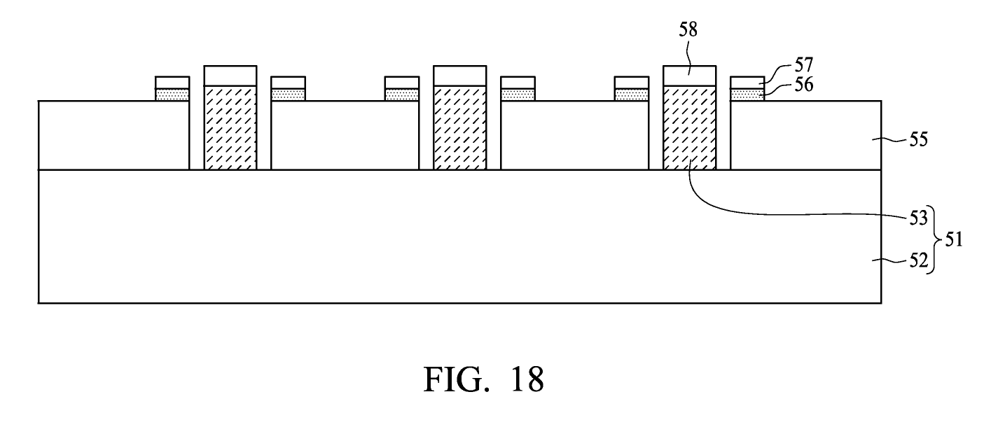

In FIG. 18, an electrical or electroless plating process is performed to form heat conducting pillars 53 on the heat conducting substrate 52 in a complementary fashion with respect to the structure shown in FIG. 16. Referring back to FIG. 18, the heat conducting pillar 53 is a heat conductor with thermal conductivity higher than 100 W/mK, and the material thereof comprises silver, copper, silver-palladium, palladium, platinum, and the alloy combinations thereof. In one embodiment of the present invention, the top surface of the heat conducting pillar 53 is equal to or higher than the top surface of other elements in the structure. A second adhesion enhancing layer 58 comprising tin or nickel/palladium/gold is formed on the heat conducting pillars 53 by an electrical plating process or a printing process in order to achieve better adhesion and lower contact resistance between different materials. In the embodiment shown in FIG. 11 of the present invention, an optical device 20 is disposed on the heat conducting pillar 53 and electrically connected to the electrical conducting pads 56 via two electrodes 22 and the corresponding first adhesion enhancing layers 57.

In light of the two abovementioned embodiments of the present invention, the method of forming the heat conducting pillar can be 1) electrical plating/electroless plating of silver, copper, silver-palladium, palladium, platinum, or combinations thereof on the heat conducting substrate, or 2) forming a layer of conductive paste through a thick film printing process, wherein the conductive paste comprises materials selected from a group comprising of silver, copper, silver-palladium, palladium, platinum powder and the alloy powder combinations thereof on the heat conducting substrate. The method of forming the electrical conducting pads can be 1) laminating a copper foil on the insulating pads, or 2) forming a layer of conductive paste though a thick film printing process, wherein the conductive paste comprises materials selected from a group consisting of silver, copper, silver-palladium, palladium, platinum powder and the alloy powder combinations thereof on the insulating pads.

In one embodiment of the present invention, the heat conducting pillars and the electrical conducting pads are made of conducting paste comprising a material selected from the group consisting of silver, copper, silver-palladium, palladium, platinum powder and the alloy powder combinations thereof. In another embodiment of the present invention, the heat conducting pillars comprise plated metals selected from the group consisting of silver, copper, silver-palladium, palladium, platinum, and the alloy combinations thereof; and the electrical conducting pads is made of conducting paste comprising a material selected from the group consisting of silver, copper, silver-palladium, palladium, platinum powder and the alloy powder combinations thereof.

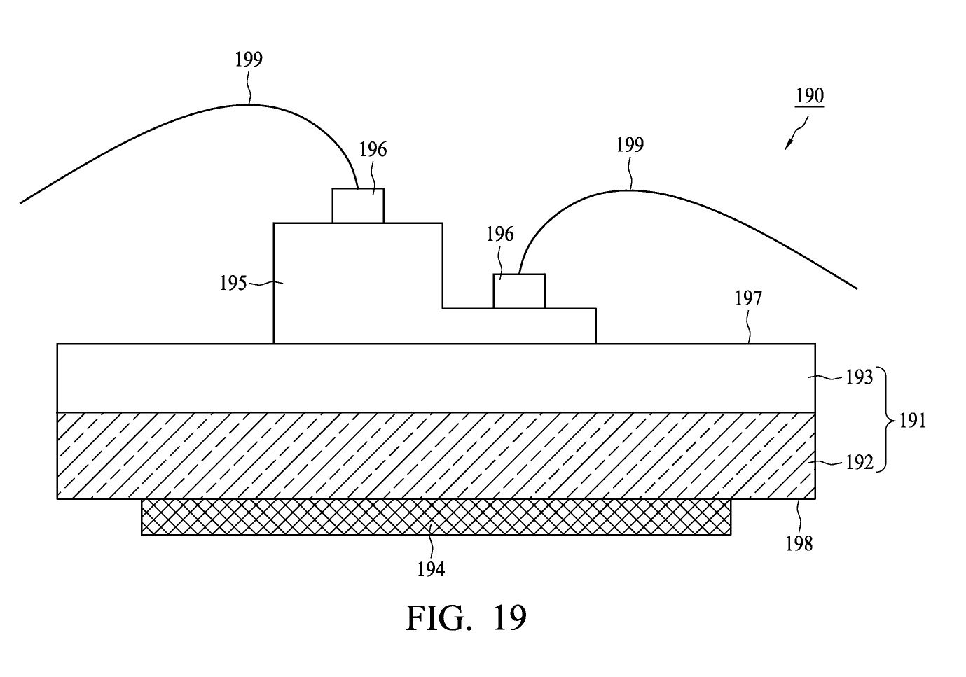

FIG. 19 is a cross sectional view of a LED chip 190 with metallization under a semiconductor substrate 191. The semiconductor substrate 191 comprises a semiconductor portion 193 and an insulating portion 192. An epitaxially grown light-emitting structure 195 is positioned on the active side 197 of the substrate 191, and a metal layer 194, preferably a gold layer, is disposed on the passive side 198 of the substrate 191. Two metal pads 196 are placed on the p and n layer of the light-emitting structure 195 respectively to be connected to an external bias (not shown) via gold wires 199. The insulating portion 192 of the substrate 191 and the metal layer 194 facilitate the chip on board (COB) packaging, which enables a more compact array assembly. The following embodiments describe the integration of the COB packaging and the corresponding thermally enhanced optical package.

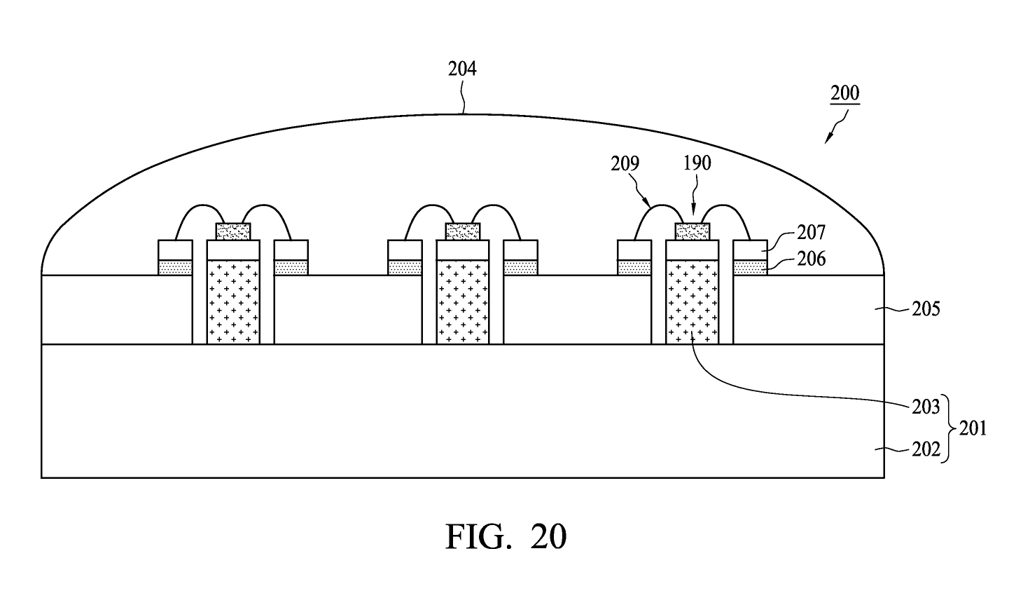

FIG. 20 is a cross sectional view illustrating a thermally enhanced COB LED package 200 according to one embodiment of the present invention. The LED COB package 200 comprises a heat conducting module 201, a plurality of insulating pads 205, and at least one electrical conducting pad 206. The heat conducting module 201 comprises a heat conducting substrate 202 and a plurality of heat conducting pillars 203 positioned on the heat conducting substrate 202. The plurality of insulating pads 205 are disposed on the heat conducting substrate 202, and the at least one electrical conducting pad 206 is disposed on the insulating pads 205 to form a bonded unit. In the present embodiment, an LED chips 190 is positioned on a heat conducting pillar 203, and is electrically connected to the electrical conducting pad 206 of the bonded unit via gold wires 209 and corresponding adhesion enhancing layers 207. The adhesion enhancing layer 207 comprising tin or nickel/palladium/gold is positioned on the electrical conducting pads 206 for better adhesion and lower contact resistance between the gold wires 209 and the electrical conducting pads 206. The heat conducting pillars 203 in the present invention are made of a conductive paste comprising a material selected from the group consisting of silver, copper, silver-palladium, palladium, platinum powder and the alloy powder combinations thereof. The electrical conducting pads 206 in the present invention comprise a metal foil, preferably a copper foil, laminating on the insulating layer 205. A light emitting array formed by a plurality of LED chips 190 are then packaged by covering fluorescent adhesive 204 on top of the thermally enhanced LED COB package 200. To sum up, a thermally enhanced optical package and the method of manufacturing thereof are disclosed. The embodiments in the present invention demonstrate different material combinations of the optical package, implemented with LED chips having different packaging complexities. The thermally enhanced optical package directs the heat generated by the LED chips to the heat sink through the heat conducting pillars. A simple manufacturing process of the heat conducting pillars substantially including an electrical or electroless plating process, a metal foil laminating process, a thick film printing process, and a patterning and etching process.

Although the present invention and its advantages have been described in detail, it should be understood that various changes, substitutions, and alterations can be made without departing from the spirit and scope of the invention as defined by the appended claims. For example, many of the processes discussed above can be implemented in different methodologies or replaced by other processes, or both.

Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A thermally enhanced optical package, comprising:
a heat conducting module, configured to dissipate the heat generated from an optical device in physical contact with the module, comprising:
a heat conducting substrate; and
a plurality of heat conducting pillars positioned on the heat conducting substrate;
a plurality of insulating pads disposed on the heat conducting substrate; and
at least one electrical conducting pad disposed on the insulating pad and electrically connected to the optical device.

2. The thermally enhanced optical package of claim 1, wherein the optical device is a light emitting diode chip completing level 1 packaging, positioned on the heat conducting pillar and electrically connected to the electrical conducting pad.

3. The thermally enhanced optical package of claim 1, wherein the optical device is a light emitting diode die without level 1 packaging, positioned on the heat conducting pillar and electrically connected to the electrical conducting pad.

4. The thermally enhanced optical package of claim 3, wherein the light emitting diode die without level 1 packaging comprises:
a semiconductor substrate having an insulating portion and a semiconductor portion on the insulating portion;
an electrical conducting layer positioned on a passive side of the semiconductor substrate, contacting the insulating portion of the semiconductor substrate; and
a light-emitting structure epitaxially grown on an active side of the semiconductor substrate, contacting the semiconductor portion of the semiconductor substrate.

5. The thermally enhanced optical package of claim 1, wherein the heat conducting substrate includes a material selected from the group consisting of aluminum, copper, and the alloy combinations thereof.

6. The thermally enhanced optical package of claim 1, wherein the heat conducting pillar is a heat conductor with a thermal conductivity greater than 100 W/mK.

7. The thermally enhanced optical package of claim 1, wherein the top surface of the heat conducting pillar is at least equal to or higher than top surfaces of other elements in the structure.

8. The thermally enhanced optical package of claim 1, wherein the insulating pads include a material selected from the group consisting of a double-sided tape and an epoxy.

9. The thermally enhanced optical package of claim 1, wherein the electrical conducting pad includes a material selected from the group consisting of copper, silver-palladium, palladium, platinum, and the alloy combinations thereof.

10. A method of manufacturing a thermally enhanced optical package, comprising the steps of:
forming a heat conducting module including a heat conducting substrate and a plurality of heat conducting pillars positioned on the heat conducting substrate;
forming a plurality of insulating pads including at least one electrical conducting pad positioned on each of the insulating pads;
binding the heat conducting module and the plurality of insulating pads; and
forming an adhesion enhancing layer on the plurality of heat conducting pillars and the at least one electrical conducting pads.

11. The method of manufacturing a thermally enhanced optical package of claim 10, further comprising the steps of:
binding an optical device on the heat conducting pillars via the adhesion enhancing layer; and
forming an electrical connection between the optical device and the electrical conducting pads.

12. The method of manufacturing a thermally enhanced optical package of claim 10, wherein the forming of the heat conducting pillars is performed by a thick film printing process, and the heat conducting pillars include conductive paste.

13. The method of manufacturing a thermally enhanced optical package of claim 10, wherein the forming of a plurality of insulating pads with at least one electrical conducting pad positioned on each of the insulating pads comprises the steps of:
attaching a metal foil on one side of a double sided adhesion layer, wherein the double sided adhesion layer is an insulator;
punching through the metal foil and the double sided adhesion layer to form a predetermined pattern;
printing a patterned gel body on the metal foil;
etching an uncovered portion of the metal foil; and
stripping the patterned gel body.

14. The method of manufacturing a thermally enhanced optical package of claim 10, wherein the forming of the adhesion enhancing layer is performed by a surface printing process or an electrical plating process.

15. A method of manufacturing a thermally enhanced optical package, comprising the steps of:
forming a plurality of insulating pads with at least one electrical conducting pad positioned on each of the insulating pads;
forming a first adhesion enhancing layer on electrical conducting pads;
combining the plurality of insulating pads with a heat conducting substrate;
forming a plurality of heat conducting pillars on the heat conducting substrate; and
forming a second adhesion enhancing layer on the heat conducting pillars.

16. The method of manufacturing a thermally enhanced optical package of claim 15, further comprising the steps of:
binding an optical device on the heat conducting pillars via the adhesion enhancing layer; and
forming an electrical connection between the optical device and the electrical conducting pads.

17. The method of manufacturing a thermally enhanced optical package of claim 15, wherein the step of forming a plurality of insulating pads with at least one electrical conducting pad positioned on each of the insulating pads comprises the steps of:
attaching a metal foil on one side of a double sided adhesion layer, wherein the double sided adhesion layer is an insulator;
punching through the metal foil and the double sided adhesion layer to form a predetermined pattern;
printing a patterned gel body on the metal foil;
etching an uncovered portion of the metal foil; and
stripping the patterned gel body.

18. The method of manufacturing a thermally enhanced optical package of claim 15, wherein the forming of the heat conducting pillars is formed by electrical or electroless plating process.

19. The method of manufacturing a thermally enhanced optical package of claim 15, wherein the forming of the first adhesion enhancing layers is performed by a surface printing process or an electrical plating process.

20. The method of manufacturing a thermally enhanced optical package of claim 15, wherein the forming of the second adhesion enhancing layers is performed by a surface printing process or an electrical plating process.
